(19) United States
(12) Patent Application Publication
(10) Pub. No.: US 2007/0045845 A1
(43) Pub. Date: Mar. 1, 2007

(54) Ball grid array interface structure and method

(76) Inventors: Anand Lal, Plantation, FL (US); Dhaval N. Shah, Sunrise, FL (US)

Correspondence Address: MOTOROLA, INC;INTELLECTUAL PROPERTY SECTION, LAW DEPT, 8000 WEST SUNRISE BLVD, FT LAUDERDAL, FL, 33322, US

(21) Appl. No.: 11/216,961

(22) Filed: Aug. 31, 2005

(51) Int. Cl. H01L 23/48

(52) U.S. Cl. 257/738

(57) ABSTRACT

A structure and method (1000) of forming an interface for a ball grid array includes forming pad (204), (1002) on a substrate (202) and creating a positive feature (206) on the pad (1004). The positive feature (206) provides an interface for a solder ball (208). The improved pad can be incorporated as part of BGA substrate or as part of a printed circuit board substrate. The positive feature (206) provides a contoured or uneven profile having vertical surfaces that increase the pad's surface area without taking up additional substrate space. The vertical surface area interrupts propagation of any fracture incurred during drop and vibration.

### FIELD OF THE INVENTION

The present invention relates generally to surface mount technology and more particularly to ball grid array interface structures.

### BACKGROUND OF THE INVENTION

Electronic products make use of surface mount technology to optimize manufacturability, reduce cost and decrease size. Surface mount technology in the form of the ball grid array (BGA) facilitates the mounting of electronic components to printed circuit boards by providing numerous solder balls beneath a BGA substrate which mount to corresponding contacts on a printed circuit board. FIG. 1 shows a cross sectional view of a BGA component 100 having a BGA substrate 102 with conventional flat pads 104 formed therein and solder ball 106 adhered thereto. Component 100 is mounted to printed circuit board 108.

Impact robustness is a key requirement for electronic products that may be subjected to drop or vibration. Drop and vibration can lead to deformations of the board introducing strain in the solder joints between the board and the BGA component assembled on the board, which can result in a fracture. Within the solder joint, the location of the fracture is usually the interface between the solder ball 106 and the pads 104 on the BGA substrate 102. Usually such issues are dealt with by controlling the intermetallic microstructure at the interface between the BGA substrate pad 104 and solder ball 106. However, the impact of such microstructural controls on the mechanical performance is often limited. The area of the pad 104 can also be increased to strengthen the joint. Increasing the pad size, however, has not proven to be an effective measure as space constraints make it difficult to accommodate. Thus, an improved means of strengthening the joint to increase robustness under impact and vibration is highly desirable.

Accordingly, there is a need for an improved surface mount structure for a ball grid array interface.

### BRIEF DESCRIPTION OF THE FIGURES

Exemplary embodiments of the invention are now described, with reference to the accompanying figures in which:

FIG. 1 shows a cross sectional view of a BGA component known in the art;

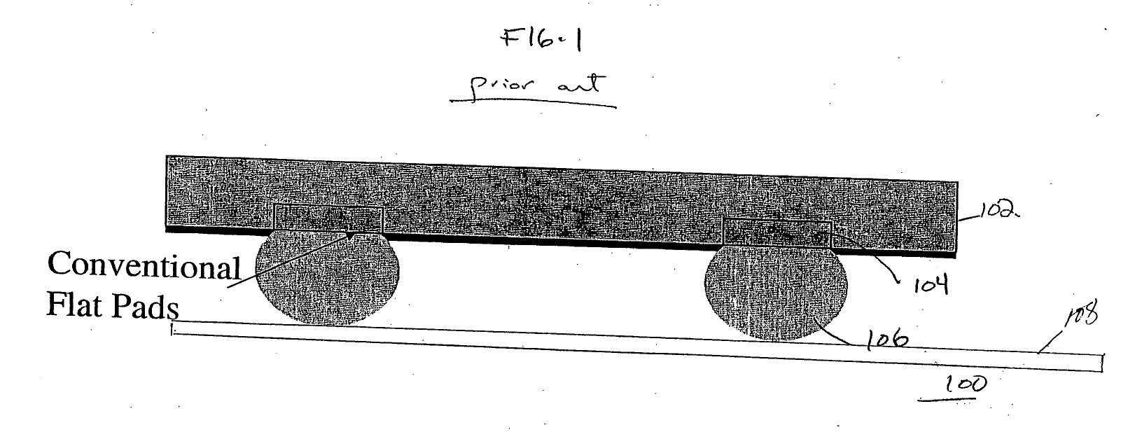

FIGS. 2, 3, 4 and shows cross sectional views of a BGA component formed in accordance with various exemplary embodiments of the invention;

FIG. 6 shows a cross sectional view of a simplified solder joint subjected to a pull test;

FIGS. 7 and 8 show and compare simulated results for a conventional flat pad solder joint subjected to the pull test of FIG. 6 and a pad with a post formed in the middle subjected to the same conditions;

FIG. 9 shows a cross sectional view of a printed circuit board formed in accordance with the present invention; and

FIG. 10 is a method of forming a ball grid array interface in accordance with the present invention.

### DETAILED DESCRIPTION OF THE PREFERRED EMBODIMENT

Briefly in accordance with the present invention, there is provided herein a substrate having pads with positive features created thereon. For the purposes of this application, a pad having a positive feature means a pad having a contoured or uneven profile, as opposed to a flat profile. The positive features can range from a simple protruding post in the middle of each pad to more complex profiles, examples of which will be provided.

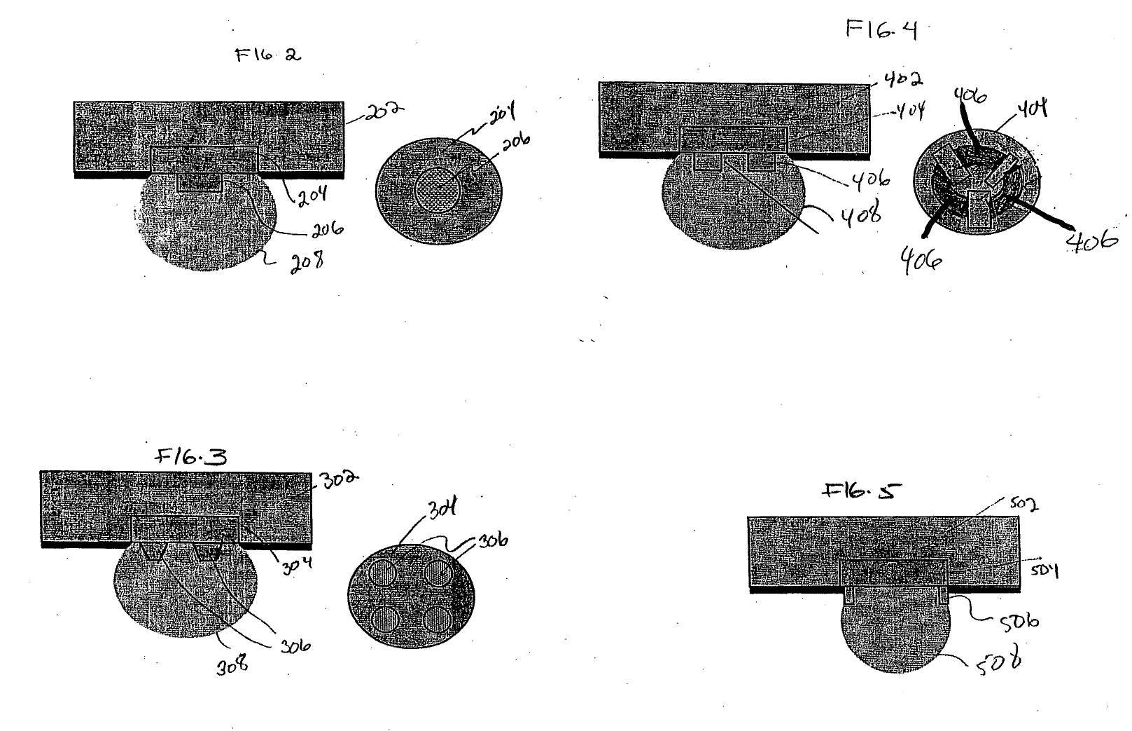

FIGS. 2, 3, 4 and 5 show cross sectional views of a ball grid array (BGA) component formed in accordance with various exemplary embodiments of the invention. In accordance with the embodiment of FIG. 2, BGA substrate 202 includes pad 204 formed therein having a positive feature, in this case a post 206, created in the middle of the pad. Solder ball 208 is bumped onto the pad's surface.

In accordance with the embodiment of FIG. 3, BGA substrate 302 includes pad 304 formed therein having a positive feature, in this case a plurality of rounded posts 306, created in the pad. Solder ball 308 is bumped onto the pad's surface.

In accordance with the embodiment of FIG. 4, BGA substrate 402 includes pad 404 formed therein having a positive feature, in this case a plurality of irregularly shaped posts 406, distributed in an irregular fashion within the pad. Solder ball 408 is bumped onto the pad's surface.

In accordance with the embodiment of FIG. 5, BGA substrate 502 includes pad 504 formed therein having a positive feature, in this case vertical walls 506, extending from the outer perimeter of the pad. Solder ball 508 is bumped onto the pad's surface.

The vertical or inclined surfaces provided by the positive features of each of the above exemplary embodiments will be exposed to lower tension and less susceptible to fracture or decohesion at the intermetallic (solder ball) and pad interface. The substrate pads on conventional ball grid array (BGA) components are always flat, or at the most have micro-vias. The use of substrate pads having contoured or uneven profiles enhances the mechanical performance of the solder joint in two ways. First, the surface area of the interface is effectively increased giving it the ability to withstand higher forces for a given interface strength. This increase is achieved without consuming additional space on the substrate. The second advantage relies on the fact that failure at the solder ball/substrate interface is an adhesive failure that occurs under tensile forces (relative to the interface). So, for a conventional flat pad on a board subjected to deformation (bending), the entire substrate/solder ball interface is perpendicular to the direction of the force and hence fractures easily under predominately tensile forces. By incorporating a positive feature(s) into the pad in accordance with the present invention, a surface is created that will break the continuity of any fracture or crack propagating along the interface.

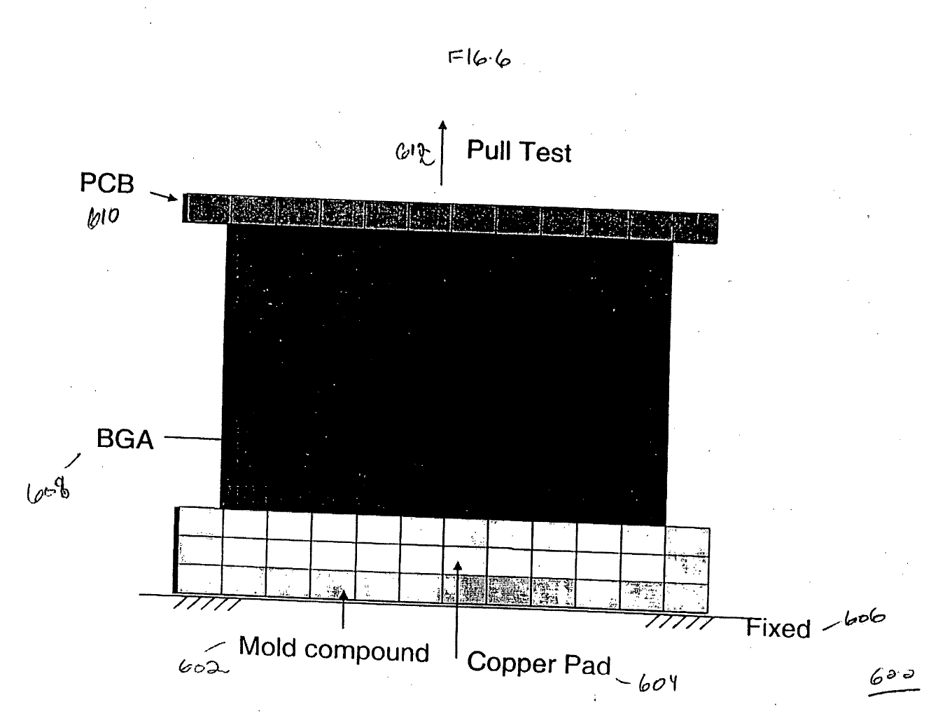

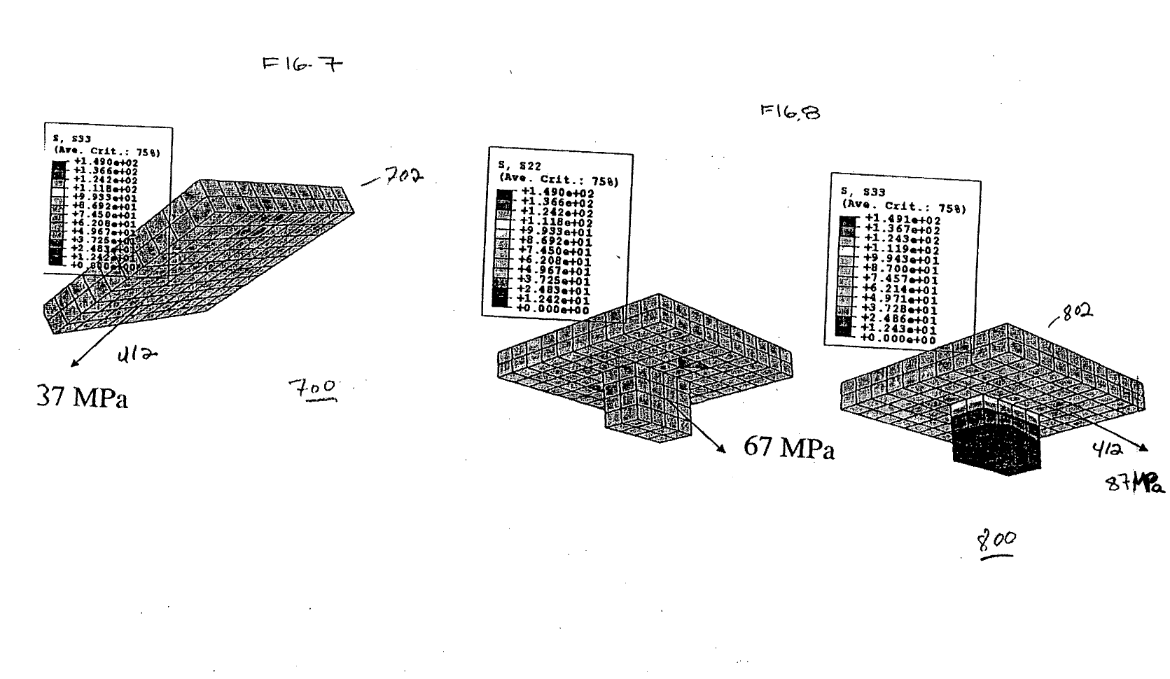

FIG. 6 shows a cross sectional view 600 of a single simplified solder joint in a BGA assembly subjected to a pull test. Cross sectional view 600 includes mold compound 602 coupling a copper pad 604 to a fixed surface 606. Copper pad 604 has a solder ball 608 formed thereon and is coupled to a printed circuit board 610 upon which is exerted a pull test 612. Simulations were performed for a flat copper pad and a copper pad with an extra post in the middle. FIGS. 7 and 8 show and compare simulated results 700, 800 for a conventional flat pad solder joint 702 subjected to the pull test and a pad with a post formed in the middle 802 subjected to the same conditions. Results 700 and 800 show the stresses generated in the copper pads during the pull test. The principal stress (S33) 412 is in a direction normal to the flat portion of the pads, in this simulation 87 MPa (Mega Pascal), for both kinds of pads. For the flat pad 702, forces during impact are sufficient to peel a solder ball at the interface. For the pad with the post 802, the principal stress in a direction normal to the vertical portion (S22) measured only 67 MPa at the interface. This principal stress on the vertical portion was even lower, measuring 37 MPa, when stresses in the solder ball were simulated. Thus, vertical surface adhesive failures are less likely with pad 802 having a positive feature formed thereon.

Other simulations of simplified tension tests have shown the stresses on the vertical surfaces of pads incorporating positive features to be roughly 42-77 percent of those in the principal loading direction. Thus, the surface along the intermetallic and solder will be less prone to separate from the substrate pad and propagation of a crack will be resisted by utilizing a pad formed in accordance with the present invention.

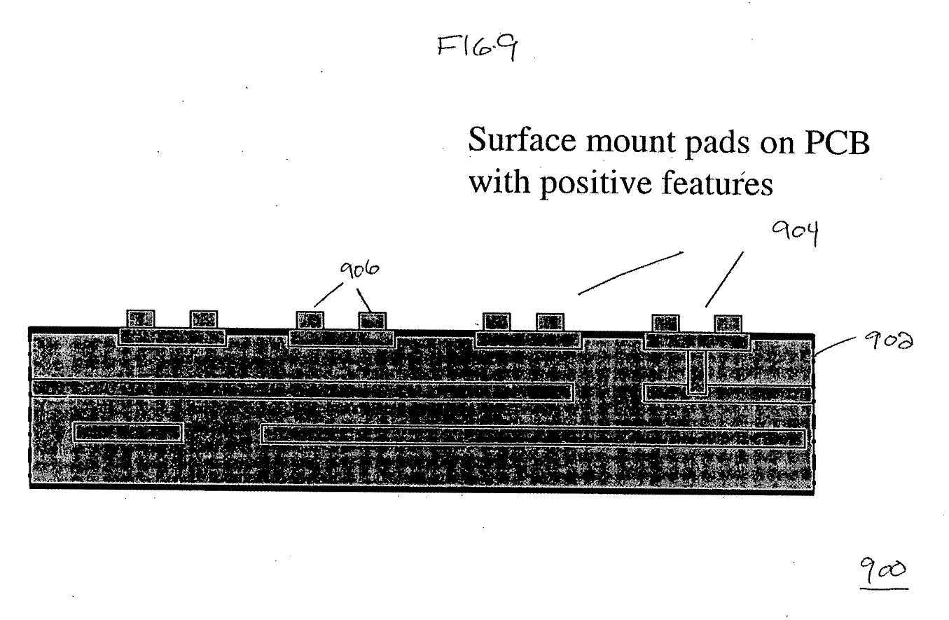

FIG. 9 is a cross sectional view 900 of a printed circuit board 902 incorporating pads 904 formed in accordance the present invention. The positive feature(s) 906 on each pad 904 provides an interface for solder balls.

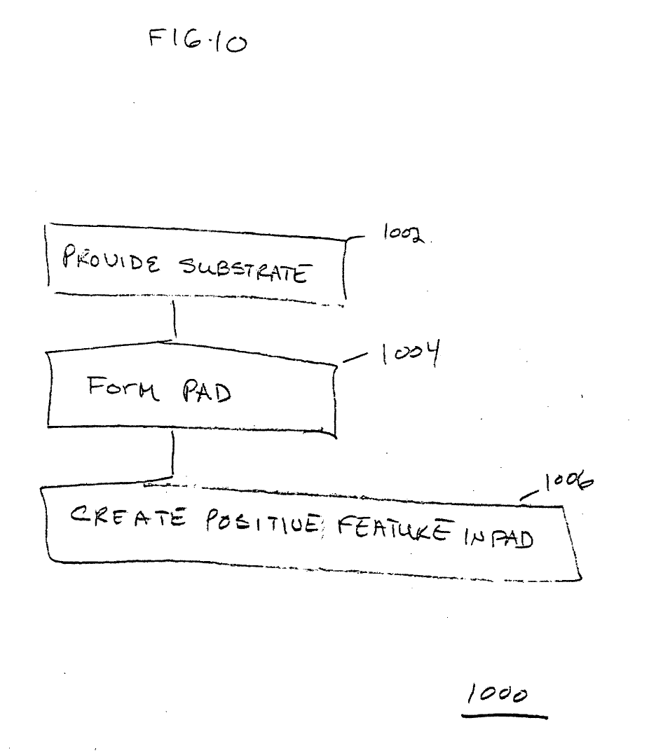

FIG. 10 is a method of forming an interface for a ball grid array in accordance with the present invention. Method 1000 begins at step 1002 by providing a substrate. Next, by forming a metalized pad on the substrate at step 1004 and creating a positive feature within the pad at step 1006, the positive feature provides an interface for a solder ball. The substrate may be a BGA substrate, for the case of a BGA component, or the substrate may be a printed circuit board substrate, for the case of a board interface.

For the case of the BGA substrate, the positive feature of the present invention can be created by, while not limited to, additional masking and plating steps during fabrication of the BGA substrate, prior to bumping. For the case of the printed circuit board substrate, the pads and positive features of the substrate mate with the solder balls of a BGA component (with or without its own positive features). Thus, the improved ball grid array interface provided by a pad formed in accordance with the present invention can be formed on the BGA component side, the printed circuit board side or both.

While the invention has been described in conjunction with specific embodiments thereof, additional advantages and modifications will readily occur to those skilled in the art. The invention, in its broader aspects, is therefore not limited to the specific details, representative apparatus, and illustrative examples shown and described. Various alterations, modifications and variations will be apparent to those skilled in the art in light of the foregoing description. Thus, it should be understood that the invention is not limited by the foregoing description, but embraces all such alterations, modifications and variations in accordance with the spirit and scope of the appended claims.

We claim:

1. An interface assembly for a ball grid array, comprising:
a substrate;
a pad coupled to the substrate; and
a positive feature formed on the pad, the pad and positive feature for adhering to a solder ball.

2. The interface assembly of claim 1, wherein the substrate comprises a ball grid array (BGA) substrate.

3. The interface assembly of claim 1, wherein the substrate comprises a printed circuit board.

4. The interface assembly of claim 1, wherein the positive feature provides an increased surface area to the pad without additional substrate space.

5. The interface assembly of claim 1, wherein the positive feature of the pad includes a vertical surface for breaking a propagation of a fracture along the interface.

6. The interface assembly of claim 1, wherein the positive feature of the pad includes an inclined surface for breaking a propagation of a fracture along the interface.

7. A surface mount component, comprising:
a ball grid array (BGA) substrate;
a pad coupled to the BGA substrate; and
at least one positive feature created on the pad;
a solder ball bumped onto the pad and positive feature.

8. The surface mount component of claim 7, wherein the at least one positive feature increases the pad's surface area without taking up additional BGA substrate space.

9. The surface mount component of claim 7, wherein the at least one positive feature of the pad includes a vertical surface.

10. The surface mount component of claim 7, wherein the at least one positive feature of the pad includes an inclined surface.

11. The surface mount component of claim 7, wherein the at least one positive feature of the pad includes a non-flat profile.

12. The surface mount component of claim 7, wherein the at least one positive feature minimizes a propagation of a fracture along an interface between the solder ball and the BGA substrate.

13. A method of forming an interface for a ball grid array, comprising the steps of:
providing a substrate;
forming pad on the substrate;
creating a positive feature on the pad, the positive feature providing an interface for a solder ball.

14. The method of claim 13, wherein the substrate comprises a ball grid array (BGA) substrate.

15. The method of claim 14, further comprising the step of bumping the pads of the BGA substrate with solder balls.

16. The method of claim 13, wherein the substrate comprises a printed circuit board.

17. The method of claim 13, wherein the positive feature interrupts prorogation of a fracture along an interface between the solder ball and substrate.
